(19) United States
(12) Patent Application Publication
(10) Pub. No.: US 2025/0248284 A1
(43) Pub. Date: Jul. 31, 2025

(54) DISPLAY DEVICE AND METHOD OF MANUFACTURING THE SAME

(71) Applicant: Samsung Display Co., LTD., Yongin-si (KR)

(72) Inventor: Ji Seong YANG, Yongin-si (KR)

(73) Assignee: Samsung Display Co., LTD., Yongin-si (KR)

(21) Appl. No.: 18/927,543

(22) Filed: Oct. 25, 2024

(30) Foreign Application Priority Data
Jan. 29, 2024 (KR) 10-2024-0013447

(51) Int. Cl. H10K 59/80; H10K 59/12; H10K 59/122; H10K 59/38

(52) U.S. Cl. CPC H10K 59/878; H10K 59/1201; H10K 59/122; H10K 59/38; H10K 59/877

(57) ABSTRACT

A method of manufacturing a display device includes forming a substrate, a pixel circuit layer, and a light emitting element layer, forming a first bank on the light emitting element layer, forming a reflective layer on the first bank, forming a second bank and a scattering layer on the reflective layer, forming a first color conversion layer and a second color conversion layer in an area surrounded by the second bank on the substrate, and forming a first capping layer on the scattering layer, the first color conversion layer, and the second color conversion layer. The reflective layer is formed through an etching process using a positive type photosensitive emulsion.

### CROSS REFERENCE TO RELATED APPLICATION(S)

This application claims priority to and benefits of Korean Patent Application No. 10-2024-0013447 under 35 U.S.C. § 119, filed on Jan. 29, 2024, in the Korean Intellectual Property Office (KIPO), the content of which in its entirety is incorporated herein by reference.

### BACKGROUND

### 1. Technical Field

The disclosure relates to a display device and a method of manufacturing the same.

### 2. Description of the Related Art

Recently, interest in an information display has been increasing. Accordingly, research and development on a display device is continuously being conducted.

The content described above is only intended to help understanding of the background technology of the technical ideas of the disclosure, and thus it cannot be understood as a content corresponding to prior art known to those skilled in the art of the disclosure.

### SUMMARY

An object to be solved by the disclosure is to provide a display device and a method of manufacturing the same capable of stably forming a bank while improving light output efficiency of the display device.

According to an embodiment of the disclosure, a method of manufacturing a display device includes forming a substrate, a pixel circuit layer, and a light emitting element layer, forming a first bank on the light emitting element layer, forming a reflective layer on the first bank, forming a second bank and a scattering layer on the reflective layer, forming a first color conversion layer and a second color conversion layer in an area surrounded by the second bank on the substrate, and forming a first capping layer on the scattering layer, the first color conversion layer, and the second color conversion layer. The reflective layer is formed through an etching process using a positive type photosensitive emulsion.

The method may further include forming an insulating layer disposed on the reflective layer and surrounding the reflective layer.

The reflective layer may surround a side surface and an upper surface of the first bank.

Each of the first color conversion layer and the second color conversion layer may include a color conversion particle capable of converting a color, and one surface of the second bank may face the first bank and the reflective layer.

The second bank and the scattering layer may include a scatterer, and the scatterer may include at least one of barium sulfate, calcium carbonate, and titanium oxide.

The second bank and the scattering layer may include a liquid-repellent material.

Each of the first bank and the second bank may have one of a square shape, a rectangular shape, and a trapezoidal shape.

The method may further include forming a first capping layer on the first and second color conversion layers.

The second bank and the scattering layer may be formed at a same time point.

The forming of the reflective layer on the first bank may include forming a metal layer on the first bank, forming a photoresist layer on the metal layer using the positive type photosensitive emulsion, removing the photoresist layer of a portion exposed through a development process, and forming the reflective layer by etching the metal layer using the remaining photoresist layer.

According to an embodiment of the disclosure, a display device includes a substrate including an area where first to third sub-pixels are formed, a first bank formed on the substrate and protruding in a first direction, a reflective layer formed on the first bank, a second bank disposed on the reflective layer and overlapping the first bank, a first color conversion layer formed in the first sub-pixel and formed in an area surrounded by the first bank on the substrate, a second color conversion layer formed in the second sub-pixel and formed in an area surrounded by the first bank on the substrate, and a scattering layer formed in the third sub-pixel, and the scattering layer and the second bank include a same material as the second bank.

The display device may further include an insulating layer disposed on the reflective layer and surrounding the reflective layer.

The reflective layer may surround a side surface and an upper surface of the first bank.

Each of the first color conversion layer and the second color conversion layer may include a color conversion particle capable of converting a color, and a surface of the second bank may face the first bank and the reflective layer.

The second bank and the scattering layer may include a scatterer, and the scatterer may include at least one of barium sulfate, calcium carbonate, and titanium oxide.

The second bank and the scattering layer may include a liquid-repellent material.

Each of the first bank and the second bank may have one of a square shape, a rectangular shape, and a trapezoidal shape.

The display device may further include a first capping layer on the first and second color conversion layers.

The display device may further include an insulating layer disposed on the reflective layer and surrounding the reflective layer. The reflective layer may surround a side surface and an upper surface of the first bank, each of the first color conversion layer and the second color conversion layer may include a color conversion particle capable of converting a color, and a surface of the second bank may face the first bank and the reflective layer.

The display device may further include a first capping layer on the first and second color conversion layers. The second bank and the scattering layer may include a scatterer, the scatterer may include at least one of barium sulfate, calcium carbonate, and titanium oxide, and each of the first bank and the second bank has one of a square shape, a rectangular shape, and a trapezoidal shape.

According to the embodiment described above, a display device and a method of manufacturing the same capable of stably forming a bank while improving light output efficiency of the display device may be provided.

An effect according to embodiments is not limited to the content described above, and further various effects are included in the present specification.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram illustrating a display device according to embodiments of the disclosure;

FIG. 2 is a schematic plan view of a display panel of FIG. 1;

FIG. 3 is a schematic cross-sectional view of the display panel of FIG. 1;

FIG. 4 is a schematic diagram of an equivalent circuit illustrating an embodiment of a pixel included in the display device of FIG. 1;

FIG. 5 is a schematic cross-sectional view taken along line I-I′ of the display panel of FIG. 2;

FIG. 6 is a schematic cross-sectional view taken along the line I-I′ according to another embodiment of the display panel of FIG. 2;

FIG. 7 is a schematic enlarged view illustrating a portion A of FIG. 5;

FIG. 8 is a schematic flowchart illustrating a method of manufacturing a display device according to an embodiment of the disclosure; and

FIGS. 9 to 18 are schematic diagrams illustrating an example of a method of manufacturing a display device.

### DETAILED DESCRIPTION OF THE EMBODIMENTS

Hereinafter, an embodiment according to the disclosure is described in detail with reference to the accompanying drawings. It should be noted that in the following description, only portions necessary for understanding an operation according to the disclosure are described, and descriptions of other portions may be omitted in order not to obscure the subject matter of the disclosure. In addition, the disclosure may be embodied in other forms without being limited to the embodiment described herein. However, the embodiment described herein is provided to describe in detail enough to easily implement the technical spirit of the disclosure to those skilled in the art to which the disclosure belongs.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as “first” and “second” may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

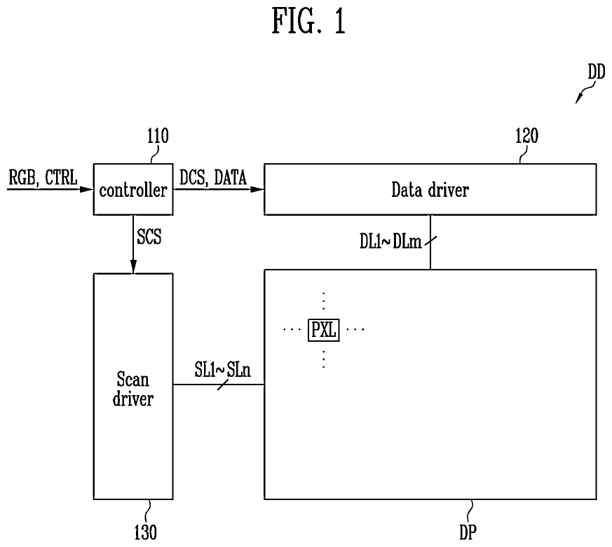

FIG. 1 is a schematic block diagram illustrating a display device according to embodiments of the disclosure.

Referring to FIG. 1, the display device DD may include a display panel DP, a controller 110, a data driver 120, and/or a scan driver 130.

The display panel DP may include pixels PXL. The display panel DP may be connected to data lines DL1 to DLm and scan lines SL1 to SLn. The data lines DL1 to DLm and the scan lines SL1 to SLn may be disposed to cross (or intersect) each other on the display panel DP. The pixels PXL may be electrically connected to the data lines DL1 to DLm and the scan lines SL1 to SLn in the display panel DP.

The display panel DP may be of various types of panels, such as an organic light emitting diode (OLED) panel. Types of lines disposed in the display panel DP may vary according to a pixel structure, a panel type, and the like.

The controller 110 may control an operation of the data driver 120 and the scan driver 130. The controller 110 may receive signals RGB and CTRL and may provide a first control signal SCS to the scan driver 130 to apply a scan signal to the scan lines SL1 to SLn according to a timing implemented in each frame. The controller 110 may provide an image data signal DATA converted from a data format of an image signal to suit an interface specification of the data driver 120. In case that the scan signal is applied to the scan lines SL1 to SLn, the controller 110 may provide a second control signal DCS to the data driver 120 to apply data voltages to the data lines DL1 to DLm.

The controller 110 may be a timing controller used in typical display technology, or may be a control device that may perform another control function by including the timing controller.

The data driver 120 may output data signals to the data lines DL1 to DLm. For example, the data driver 120 may receive the second control signal DCS and the image data signal DATA from the controller 110. The data driver 120 may convert the image data signal DATA into the data signals and output the data signals to the data lines DL1 to DLm. The data signals may be analog voltages corresponding to grayscale values of the image data signal DATA. For example, in case that a specific scan line is selected by the scan driver 130, the data driver 120 may supply analog data voltages to the data lines DL1 to DLm.

The scan driver 130 may receive the first control signal SCS from the controller 110. The scan driver 130 may output a scan signal to the scan lines SL1 to SLn. The scan driver 130 may sequentially supply the scan signals to the scan lines SL1 to SLn according to the first control signal SCS from the controller 110. The pixels PXL receiving each scan signal may receive analog voltages of grayscale values corresponding to the image data signal DATA and output light of a luminance corresponding to the received analog voltages in response to an emission control signal. Accordingly, an image may be displayed on the display panel DP.

In FIG. 1, for convenience of description, the data driver 120 and the scan driver 130 are shown as separate configurations, respectively, but the disclosure is not limited thereto. For example, at least a portion of the data driver 120 and the scan driver 130 may be integrated into one driving circuit, one module, or the like.

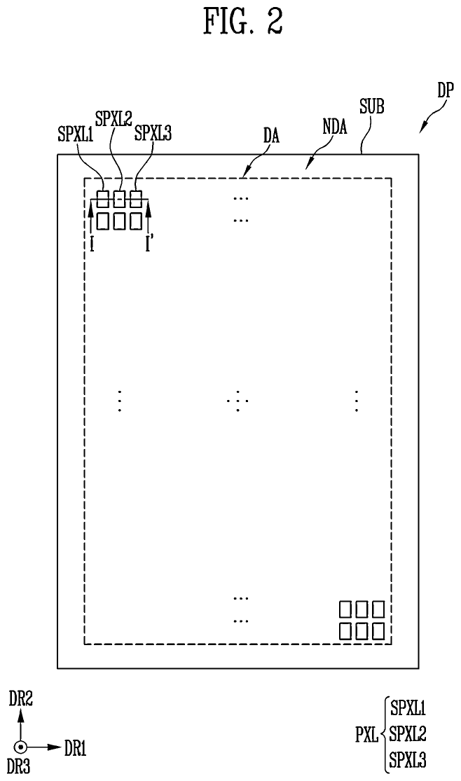

FIG. 2 is a schematic plan view of the display panel of FIG. 1.

Referring to FIG. 2, the display panel DP and a substrate SUB for forming the same may include a display area DA for displaying an image and a non-display area NDA except for the display area DA. The display area DA may configure a screen on which an image is displayed, and the non-display area NDA may be a remaining area except for the display area DA.

For convenience of description, a structure of the display panel DP is briefly shown in FIG. 2 based on the display area DA. However, although not shown in FIG. 2, at least one driving circuit (for example, at least one of the scan driver and the data driver), lines, and/or pads may be further disposed on the display panel DP.

Pixel parts may be disposed in the display area DA. Each pixel part may include a first sub-pixel SPXL1, a second sub-pixel SPXL2, and/or a third sub-pixel SPXL3. In FIG. 2, the first sub-pixel SPXL1, the second sub-pixel SPXL2, and the third sub-pixel SPXL3 included in a pixel part (or pixel unit; hereinafter “pixel part”) are shown for clear and concise description. Other pixel parts may also be understood to include the first sub-pixel SPXL1, the second sub-pixel SPXL2, and the third sub-pixel SPXL3.

Hereinafter, in case that at least one pixel among the first sub-pixel SPXL1, the second sub-pixel SPXL2, and the third sub-pixel SPXL3 is arbitrarily referred to, or in case that two or more types of pixels are collectively referred to, the at least one pixel or the two or more types of pixels are referred to as a “pixel PXL” or “pixels PXL”.

The pixels PXL may be regularly arranged according to a stripe or PENTILE™ arrangement structure, or the like. However, an arrangement structure of the pixels PXL is not limited thereto, and the pixels PXL may be arranged in the display area DA in various structures and/or methods.

According to an embodiment, two or more types of pixels PXL emitting light of different colors may be disposed in the display area DA. For example, in the display area DA, the first sub-pixel SPXL1 emitting light of a first color, the second sub-pixel SPXL2 emitting light of a second color, and the third sub-pixel SPXL3 emitting light of a third color may be arranged. At least one of the first to third sub-pixels SPXL1, SPXL2, and SPXL3 disposed to be adjacent to each other may configure one pixel part capable of emitting light of various colors. For example, the first sub-pixel SPXL1 may be a red pixel emitting red light, the second sub-pixel SPXL2 may be a green pixel emitting green light, and the third sub-pixel SPXL3 may be a blue pixel emitting blue light, but the disclosure is not limited thereto.

However, in FIG. 2, one first sub-pixel SPXL1, one second sub-pixel SPXL2, and one third sub-pixel SPXL3 configuring the pixel part are shown, but the disclosure is not limited thereto. For example, the pixel part may include one first sub-pixel SPXL1, two second sub-pixels SPXL2, and one third sub-pixel SPXL3.

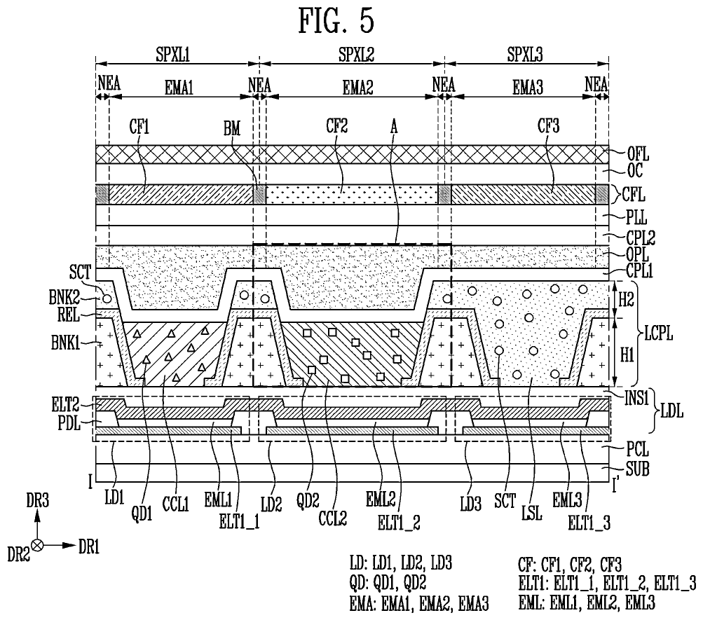

The first sub-pixel SPXL1, the second sub-pixel SPXL2, and the third sub-pixel SPXL3 may respectively include a first light emitting element LD1 (see FIG. 5), a second light emitting element LD2 (see FIG. 5), and a third light emitting element LD3 (see FIG. 5) as a light source. However, a color of the light emitted from each of the pixels PXL may variously change.

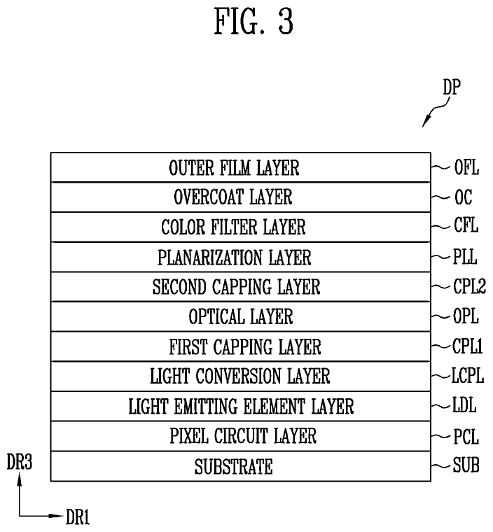

FIG. 3 is a schematic cross-sectional view of the display panel of FIG. 1.

Referring to FIG. 3, the display panel DP may include a substrate SUB, a pixel circuit layer PCL, a light emitting element layer LDL, a light conversion layer LCPL, a first capping layer CPL1, an optical layer OPL, a second capping layer CPL2, a planarization layer PLL, a color filter layer CFL, an overcoat layer OC, and/or an outer film layer OFL.

The substrate SUB may include a semiconductor substrate. As an example, the substrate SUB may include a silicon bulk wafer or an epitaxial wafer. The epitaxial wafer may include a crystalline material layer, e.g., an epitaxial layer, grown by an epitaxial process on a bulk substrate. The substrate SUB is not limited to the bulk wafer or the epitaxial wafer, and may be formed using various wafers such as a polished wafer, an annealed wafer, and silicon-on-insulator (SOI) wafer.

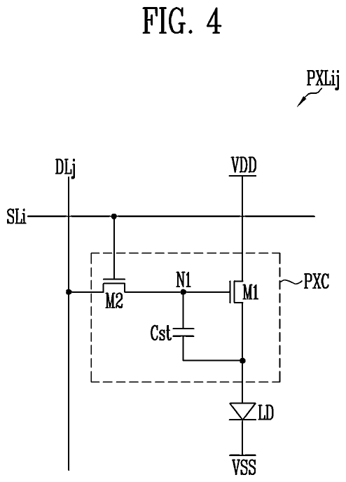

The pixel circuit layer PCL may be disposed on the substrate SUB and may include circuit elements of a pixel circuit PXC (see FIG. 4) and at least one insulating layer positioned between the circuit elements. The circuit elements may include transistors and signal lines connected to the transistors. For example, the transistors may be metal-oxide-semiconductor field-effect transistors (MOSFETs), but are not limited thereto. The circuit elements may include a gate electrode, source/drain areas, and a channel area.

The above-described substrate SUB and pixel circuit layer PCL may be formed by applying a semiconductor process and equipment, but are not limited thereto.

The light emitting element layer LDL may include a light emitting element LD (see FIG. 4) that emits light. The light emitting element LD may be positioned in each of the first to third pixels PXL1 to PXL3. The light emitting element LD may include a first electrode, light emitting layers, and a second electrode. The first electrode may be anode electrodes of the light emitting element LD, and the second electrode may be cathode electrodes of the light emitting element LD.

The light conversion layer LCPL may be disposed on the light emitting element layer LDL. The light conversion layer LCPL may change a wavelength (or color) of light emitted from the light emitting element layer LDL using a quantum dot. The light conversion layer LCPL may be formed through a continuous process on a base surface provided by the light emitting element layer LDL.

However, although it has been described that the light conversion layer LCPL may be provided separately from the light emitting element layer LDL, the light conversion layer LCPL is not limited thereto. For example, a light emitting element provided in the light emitting element layer LDL may be implemented as a light emitting element (quantum dot display element) that emits light by changing a wavelength of emitted light using a quantum dot.

The first capping layer CPL1 may be disposed on the light conversion layer LCPL. The first capping layer CPL1 may cover (or overlap) the light conversion layer LCPL. The first capping layer CPL1 may prevent an impurity such as moisture or air from permeating from an outside and damaging or contaminating the light conversion layer LCPL.

The optical layer OPL may be disposed on the first capping layer CPL1. The optical layer OPL may serve to improve light extraction efficiency by recycling light provided from the light conversion layer LCPL by total reflection.

The second capping layer CPL2 may be disposed on the optical layer OPL. The second capping layer CPL2 may cover the optical layer OPL. The second capping layer CPL2 may prevent an impurity such as moisture or air from permeating from the outside and damaging or contaminating the optical layer OPL.

The planarization layer PLL may be disposed on the second capping layer CPL2. The planarization layer PLL may include an organic material such as acrylic resin, epoxy resin, phenolic resin, polyamide resin, polyimide resin, polyester resin, polyphenylenesulfide resin, or benzocyclobutene (BCB). However, embodiments of the disclosure are not limited thereto, and the planarization layer PLL may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The color filter layer CFL may be disposed on the planarization layer PLL. The color filter layer CFL may selectively transmit light emitted from each light emitting element LD in an image display direction (or a third direction DR3) of the display device DD, but is not limited thereto.

The overcoat layer OC may be disposed on the color filter layer CFL. The overcoat layer OC may be a protective layer that covers lower members including the color filter layer CFL from an external influence. The overcoat layer OC may be a planarization layer and may include an organic material. However, an embodiment of the disclosure is not limited thereto.

The outer film layer OFL may be disposed on the overcoat layer OC. The outer film layer OFL may include one or more of a polyethyleneterephthalate (PET) film, a low-reflection film, a polarizing film, and a transmittance controllable film.

FIG. 4 is a schematic diagram of an equivalent circuit illustrating an embodiment of the pixel included in the display device of FIG. 1.

In FIG. 4, for convenience of description, a pixel PXLij disposed in an i-th row and j-th column is shown as an example.

Referring to FIG. 4, the pixel PXLij may include a pixel circuit PXC connected to an i-th scan line SLi and a j-th data line DLj, and a light emitting element LD connected to the pixel circuit PXC.

According to an embodiment, the light emitting element LD may be selected as an organic light emitting diode. The light emitting element LD may be selected as an inorganic light emitting diode, such as a micro light emitting diode (LED) or a quantum dot LED. The light emitting element LD may be an element configured of an organic material and an inorganic material in combination.

The pixel circuit PXC may include first and second transistors M1 and M2 and a storage capacitor Cst.

According to an embodiment, the first transistor M1 may include a drain electrode connected to first power VDD, a source electrode connected to a pixel electrode (for example, an anode electrode of the light emitting element LD), and a gate electrode connected to a first node N1. According to an embodiment, the drain electrode and the source electrode of the first transistor M1 may be changed according to a polarity of a voltage applied to the first transistor M1 and/or a type of the first transistor M1.

The first transistor M1 may control the driving current flowing from the first power VDD to second power VSS via the light emitting element LD in response to a voltage of the first node N1. For example, the first transistor M1 may be a driving transistor that controls the driving current of the pixel PXLij. According to an embodiment, the first power VDD and the second power VSS may be high-potential pixel power and low-potential pixel power, respectively.

According to an embodiment, the second transistor M2 may include a drain electrode connected to the j-th data line DLj, a source electrode connected to the first node N1, and a gate electrode connected to the i-th scan line SLi. According to an embodiment, the drain electrode and the source electrode of the second transistor M2 may be changed according to a polarity of a voltage applied to the second transistor M2 and/or a type of the second transistor M2. The second transistor M2 may be turned on when a scan signal having a gate on voltage (for example, a high voltage) is supplied from the i-th scan line SLi. In case that the second transistor M2 is turned on, the j-th data line DLj and the first node N1 may be electrically connected. For example, the second transistor M2 may be a switching transistor that controls a connection between the pixel PXLij and the j-th data line DLj.

According to an embodiment, the storage capacitor Cst may be connected between one electrode, for example, the source electrode, of the first transistor M1 and the first node N1. The storage capacitor Cst may store a voltage corresponding to the data signal supplied to the first node N1 and maintain the stored voltage during a period (e.g., a predetermined or selectable period). For example, the storage capacitor Cst may maintain the stored voltage until a data signal of a next frame is supplied. According to an embodiment, a connection position of the storage capacitor Cst may be changed. For example, the storage capacitor Cst may be connected between the first power VDD and the first node N1.

According to an embodiment, the light emitting element LD may be connected between the first transistor M1 and the second power VSS. For example, the light emitting element LD may include the anode electrode connected to the source electrode of the first transistor M1 and a cathode electrode connected to the second power VSS. The light emitting element LD may emit light with a luminance corresponding to the driving current controlled by the first transistor M1.

FIG. 5 is a schematic cross-sectional view taken along line I-I′ of FIG. 2 according to an embodiment.

Referring to FIG. 5, the display panel DP may include the substrate SUB, the pixel circuit layer PCL, the light emitting element layer LDL, the light conversion layer LCPL, the first capping layer CPL1, the optical layer OPL, the second capping layer CPL2, the planarization layer PLL, the color filter layer CFL, the overcoat layer OC, and/or the outer film layer OFL. A content that overlaps the description of the pixel circuit layer PCL with reference to FIG. 3 may be omitted below.

The substrate SUB may configure a base member of the display panel DP. The substrate SUB may be a rigid or flexible substrate or film. For example, the substrate SUB may be a rigid substrate formed of glass or tempered glass, a flexible substrate (or thin film) formed of a plastic or metal material, or at least one insulating layer. A material and/or a physical property of the substrate SUB is not particularly limited. In an embodiment, the substrate SUB may be substantially transparent. Here, “substantially transparent” may mean that light may be transmitted at a transmittance (e.g., a predetermined or selectable transmittance) or more. In another embodiment, the substrate SUB may be translucent or opaque. The substrate SUB may include a reflective material according to an embodiment.

The light emitting element layer LDL may include the first light emitting element LD1 positioned in the first sub-pixel SPXL1, the second light emitting element LD2 positioned in the second sub-pixel SPXL2, and/or the third light emitting element LD3 positioned in the third sub-pixel SPXL3. The light emitting element layer LDL may include a pixel defining layer PDL and a first insulating layer INS1.

The first to third light emitting elements LD1 to LD3 may include first electrodes ELT1, light emitting layers EML, and second electrodes ELT2.

The first light emitting element LD1 may include a (1_1)-th electrode ELT1_1, a first light emitting layer EML1, and the second electrode ELT2. The second light emitting element LD2 may include a (1_2)-th electrode ELT1_2, a second light emitting layer EML2, and the second electrode ELT2. The third light emitting element LD3 may include a (1_3)-th electrode ELT1_3, a third light emitting layer EML3, and the second electrode ELT2.

Each of the (1_1)-th electrode ELT1_1, the (1_2)-th electrode ELT1_2, and the (1_3)-th electrode ELT1_3 may be provided and/or formed on the pixel circuit layer PCL of the corresponding pixel. For example, the (1_1)-th electrode ELT1_1, the (1_2)-th electrode ELT1_2, and the (1_3)-th electrode ELT1_3 may be formed through a same process, may include a same material, and may be positioned in a same layer. For example, the (1_1)-th electrode ELT1_1, the (1_2)-th electrode ELT1_2, and the (1_3)-th electrode ELT1_3 may be provided and/or formed on an insulating layer of the pixel circuit layer PCL having a flat surface through a photolithography process using a mask.

The (1_1)-th electrode ELT1_1, the (1_2)-th electrode ELT1_2, and the (1_3)-th electrode ELT1_3 may be disposed to be spaced apart from each other. The (1_1)-th electrode ELT1_1 may be an anode electrode of the first light emitting element LD1, the (1_2)-th electrode ELT1_2 may be an anode electrode of the second light emitting element LD2, and the (1_3)-th electrode ELT1_3 may be an anode electrode of the third light emitting element LD3.

The (1_1)-th electrode ELT1_1, the (1_2)-th electrode ELT1_2, and the (1_3)-th electrode ELT1_3 may be formed of a material having a reflectance so that light emitted from the light emitting layers EML may proceed in the image display direction. As an example, the (1_1)-th electrode ELT1_1, the (1_2)-th electrode ELT1_2, and the (1_3)-th electrode ELT1_3 may be formed of a conductive material (or substance). For example, the (1_1)-th electrode ELT1_1, the (1_2)-th electrode ELT1_2, and the (1_3)-th electrode ELT1_3 may include a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. However, this is merely an example, and the (1_1)-th electrode ELT1_1, the (1_2)-th electrode ELT1_2, and the (1_3)-th electrode ELT1_3 may be provided and/or formed as multiple layers in which at least two or more materials among metals, alloys, conductive oxides, and conductive polymers are stacked each other.

The pixel defining layer PDL may be positioned in a non-emission area NEA and may be a structure that defines first to third emission areas EMA1 to EMA3. As an example, the pixel defining layer PDL may be a structure positioned on the pixel circuit layer PCL in the non-emission area NEA, defining the first emission area EMA1 of the first sub-pixel SPXL1, defining the second emission area EMA2 of the second sub-pixel SPXL2, and defining the third emission area EMA3 of the third sub-pixel SPXL3.

The pixel defining layer PDL may be configured of an organic insulating layer including an organic material. The organic material may include acryl resin, epoxy resin, phenolic resin, polyamide resin, polyimide resin, and the like. According to an embodiment, the pixel defining layer PDL may include a light absorbing material or may be coated with a light absorbent to serve to absorb light input from an outside. For example, the pixel defining layer PDL may include a carbon-based black pigment, but is not limited thereto.

The pixel defining layer PDL may protrude from a surface (or an upper surface) of the pixel circuit layer PCL in the third direction DR3.

The first light emitting layer EML1 may be disposed on the (1_1)-th electrode ELT1_1 exposed by the pixel defining layer PDL. The second light emitting layer EML2 may be disposed on the (1_2)-th electrode ELT1_2 exposed by the pixel defining layer PDL. The third light emitting layer EML3 may be disposed on the (1_3)-th electrode ELT1_3 exposed by the pixel defining layer PDL.

The first to third light emitting layers EML1 to EML3 may configure the light emitting layers EML of the first to third pixels PXL1 to PXL3. The light emitting layers EML may include a light generation layer that emits light, an electron transport layer that transports an electron, a hole transport layer that transports a hole, and the like, but are not limited thereto.

The second electrode ELT2 may be disposed on the light emitting layers EML and may cover the light emitting layers EML. The second electrode ELT2 may be disposed on the first light emitting layer EML1 of the first sub-pixel SPXL1, the second light emitting layer EML2 of the second sub-pixel SPXL2, and the third light emitting layer EML3 of the third sub-pixel SPXL3. The second electrode ELT2 may be commonly provided to the first to third pixels PXL1 to PXL3. The second electrode ELT2 may be provided in a plate shape over the entire display area DA, but is not limited thereto. The second electrode ELT2 may be a second conductive layer disposed on the pixel circuit layer PCL, but is not limited thereto.

The second electrode ELT2 may be a thin metal layer having a thickness sufficient to transmit light emitted from each of the first to third light emitting layers EML1 to EML3. The second electrode ELT2 may be formed of a metal material or a transparent conductive material to have a relatively thin thickness. For example, the second electrode ELT2 may be formed of various transparent conductive materials. For example, the second electrode ELT2 may include at least one of various transparent conductive materials including indium tin oxide (ITO), indium zinc oxide (IZO), indium tin zinc oxide (ITZO), aluminum zinc oxide (AZO), gallium zinc oxide (GZO), zinc tin oxide (ZTO), and gallium tin oxide (ZTO). The second electrode ELT2 may be implemented as substantially transparent or translucent to satisfy a transmittance (e.g., a predetermined or selectable transmittance). Accordingly, light emitted from each of the first to third light emitting layers EML1 to EML3 positioned under the second electrode ELT2 may pass through the second electrode ELT2 and may be emitted upward.

In embodiments, in each of the first to third pixels PXL1 to PXL3, a hole injected from the first electrodes ELT1 and an electron injected from the second electrode ELT2 may be transported into the light emitting layers EML. Through this, an exciton may be formed, and in case that the exciton transitions from an excited state to a ground state, light may be generated and may be emitted in a form of visible light.

The first insulating layer INS1 may be disposed on the second electrode ELT2. The first insulating layer INS1 may be provided as one or more insulating layers and/or protective layers covering the first to third light emitting layers EML1 to EML3 and/or the second electrode ELT2.

The first insulating layer INS1 may be provided as a thin-film encapsulation layer that seals the light emitting element layer LDL. The thin-film encapsulation layer may protect the first to third light emitting elements LD1 to LD3 from moisture/oxygen and may protect the first to third light emitting elements LD1 to LD3 from a foreign substance such as dust. For example, the first insulating layer INS1 may be provided in a form of a structure in which at least one inorganic layer and at least one organic layer are alternately stacked each other.

According to an embodiment, the inorganic layer may include at least one of silicon nitride (SiNx), silicon oxide (SiOx), silicon oxynitride (SiOxNy), and aluminum oxide (AlxOy). For example, the organic layer may include at least one of acryl resin, epoxy resin, phenolic resin, polyamide resin, and polyimide resin. However, examples of the inorganic layer and the organic layer are not limited thereto.

The light conversion layer LCPL may include a first bank BNK1, a second bank BNK2, a reflective layer REL, a first color conversion layer CCL1, a second color conversion layer CCL2, and/or a scattering layer LSL.

An emission area EMA may overlap an opening defined by the first bank BNK1 in a plan view. The first to third light emitting elements LD1 to LD3 may be disposed in the emission area EMA.

The first to third light emitting elements LD1 to LD3 may not be disposed in the non-emission area NEA. A portion of the non-emission area NEA may overlap a bank BNK in a plan view.

The first bank BNK1 may form (or provide) the opening. For example, the first bank BNK1 may have a shape that protrudes in a thickness direction (for example, the third direction DR3) of the substrate SUB and may have a shape that surrounds an area (e.g., a predetermined or selectable area). Accordingly, the opening in which the first bank BNK1 is not disposed may be formed.

The opening formed by the first bank BNK1 may mean an area in which fluid may be accommodated.

According to an embodiment, the first color conversion layer CCL1, the second color conversion layer CCL2, and the scattering layer LSL may be disposed in the opening defined by the first bank BNK1.

The first bank BNK1 may be formed to have an inclined surface inclined at an angle (e.g., a predetermined or selectable angle) with respect to the substrate SUB. However, an embodiment of the disclosure is not limited thereto, and the first bank BNK1 may have a sidewall of a curved surface, a step shape, or the like. For example, the first bank BNK1 may have a cross-section of a semicircular or semielliptical shape, or the like.

The first bank BNK1 may form a surface on which the reflective layer REL is arranged. As the first bank BNK1 has a shape that protrudes in the thickness direction (for example, the third direction DR3) of the substrate SUB, a function of the reflective layer REL as a reflective member may be performed more efficiently.

The first bank BNK1 may include an organic material such as acrylic resin, epoxy resin, phenolic resin, polyamide resin, polyimide resin, polyester resin, polyphenylenesulfide resin, or benzocyclobutene (BCB). However, an embodiment of the disclosure is not limited thereto, and the first bank BNK1 may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The second bank BNK2 may be disposed on the reflective layer REL. The second bank BNK2 may protrude in the thickness direction (for example, the third direction DR3) of the substrate SUB. The second bank BNK2 may form an opening. The opening formed by the second bank BNK2 may form a space where the first color conversion layer CCL1 and the second color conversion layer CCL2 are provided. For example, a desired type and/or amount of color conversion layer may be provided (or supplied) in a space partitioned by the second bank BNK2. According to an embodiment, the second bank BNK2 may include a liquid-repellent material suitable for efficiently forming the first and second color conversion layers CCL1 and CCL2. The liquid-repellent material may include an organic polymer material having liquid repellency. For example, the liquid-repellent material may include a polymer material in which a fluorine group (F) is mixed with an organic material such as polyimide (for example, a vinyl-based polymer having a perfluoroalkyl group (Rf group) in a side chain or silicone containing a perfluoroalkyl group).

The second bank BNK2 may include an organic material such as acrylic resin, epoxy resin, phenolic resin, polyamide resin, polyimide resin, polyester resin, polyphenylenesulfide resin, or benzocyclobutene (BCB). However, an embodiment of the disclosure is not limited thereto, and the second bank BNK2 may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

A surface of the second bank BNK2 may face the reflective layer REL. The second bank BNK2 may be exposed toward the first and second color conversion layers CCL1 and CCL2. The second bank BNK2 having liquid repellency suitable for processing may contact the first and second color conversion layers CCL1 and CCL2. Accordingly, the first and second color conversion layers CCL1 and CCL2 may be prevented from being overflowed, and ultimately, the color conversion layer may be provided efficiently.

According to an embodiment, each of the first bank BNK1 and the second bank BNK2 may include a material (e.g., a predetermined or selectable material). According to an embodiment, the first bank BNK1 and the second bank BNK2 may include a same material.

The first bank BNK1 and the second bank BNK2 may overlap each other in a plan view. Accordingly, an area where the light emitting element LD is disposed and an area where the color conversion layer is disposed may be substantially identically provided.

The first bank BNK1 may have a first height H1. The second bank BNK2 may have a second height H2. Each of the first height H1 and the second height H2 may mean a maximum height of the first bank BNK1 and the second bank BNK2 in the thickness direction (for example, the third direction DR3) of the substrate SUB. According to an embodiment, the first height H1 may be greater than the second height H2. According to an embodiment, the second height H2 may be about 0.3 times or less than the first height H1. As another example, according to another embodiment, the second height H2 may be about 0.2 times or less than the first height H1. In this case, reflective electrodes REL and may form a wide reflective wall on the first bank BNK1, and thus light output efficiency of the display device DD may be further improved. The second bank BNK2 may have a liquid repellency (e.g., a predetermined or selectable liquid repellency) to define an area where the first and second color conversion layers CCL1 and CCL2 are provided. To this end, the second bank BNK2 may not be covered by the reflective layer REL. By appropriately controlling the height of the second bank BNK2, which does not form a reflective surface, a process for forming the first and second color conversion layers CCL1 and CCL2 may proceed smoothly, and light output efficiency of the display panel DP may be further increased since the wide reflective wall is formed.

The reflective layer REL may function as a reflective member. For example, the reflective layer REL may at least partially cover a side surface and/or an upper surface of the first bank BNK1. For example, the reflective layer REL may include an inclined surface or a curved surface having a shape corresponding to a shape of the first bank BNK1. Accordingly, the reflective layer REL as a reflective member may reflect the light emitted from the light emitting element layer LDL and guide the light in a display direction (for example, the third direction DR3) of the display panel DP. Accordingly, light output efficiency of the display panel DP may be improved.

According to an embodiment, the reflective layer REL may have a reflectance (e.g., a predetermined or selectable reflectance). For example, the reflective layer REL may have a reflectance of about 50% or more. As another example, according to an embodiment, the reflective layer REL may have a reflectance of about 70% or more. However, the disclosure is not limited to the example described above.

The first color conversion layer CCL1 may be positioned in the first sub-pixel SPXL1, the second color conversion layer CCL2 may be positioned in the second sub-pixel SPXL2, and the scattering layer LSL may be positioned in the third sub-pixel SPXL3.

In an embodiment, the first to third sub-pixels SPXL1, SPXL2, and SPXL3 may include first to third light emitting elements LD1 to LD3 that emit light of a same color. For example, the first to third sub-pixels SPXL1, SPXL2, and SPXL3 may include light emitting elements LD that emit light of a third color (or blue). As the first color conversion layer CCL1, the second color conversion layer CCL2, and the scattering layer LSL including color conversion particles are respectively disposed on the first to third sub-pixels SPXL1, SPXL2, and SPXL3, an image of a full color may be displayed.

The first color conversion layer CCL1 may include first color conversion particles that convert the light of the third color emitted from the first light emitting element LD1 into light of a first color (or red). Quantum dots QD may be used for color conversion. For example, the first color conversion layer CCL1 may include first quantum dots QD1 dispersed in a matrix material (e.g., a predetermined or selectable matrix material) such as a base resin. The first quantum dot QD1 may absorb blue light and shift a wavelength of the blue light according to energy transition to emit red light.

The second color conversion layer CCL2 may include second color conversion particles that convert the light of the third color emitted from the second light emitting element LD2 into light of a second color (or green). For example, the second color conversion layer CCL2 may include second quantum dots QD2 dispersed in a matrix material (e.g., a predetermined or selectable matrix material) such as base resin. The second quantum dot QD2 may absorb blue light and shift the wavelength of the blue light according to energy transition to emit green light.

In an embodiment, as the blue light having a relatively short wavelength in a visible light region is incident on each of the first quantum dot QD1 and the second quantum dot QD2, an absorption coefficient of the first quantum dot QD1 and the second quantum dot QD2 may be increased. Accordingly, finally, efficiency of light emitted from the first sub-pixel SPXL1 and the second sub-pixel SPXL2 may be improved, and excellent color reproducibility may be ensured. As a light emitting part of the first to third sub-pixels SPXL1, SPXL2, and SPXL3 are configured using the first to third light emitting elements LD1 to LD3 (for example, blue light emitting elements) of a same color, a manufacturing efficiency of the display panel DP may be increased.

The scattering layer LSL may be provided to efficiently use the light of the third color (or blue) emitted from the third light emitting element LD3. The scattering layer LSL and the second bank BNK2 may be patterned in a same process. The scattering layer LSL and the second bank BNK2 may be formed at a same time point. The scattering layer LSL and the second bank BNK2 may include a same material. In this case, the number of masks may be reduced, and a manufacturing process may be simplified, thereby reducing a process cost. The scattering layer LSL may include at least one type of scatterer SCT in order to efficiently use light emitted from the light emitting element LD. For example, the scatterer SCT of the scattering layer LSL may include at least one of barium sulfate (BaSO4), calcium carbonate (CaCO3), titanium oxide (TiO2), silicon oxide (SiO2), aluminum oxide (Al2O3), zirconium oxide (ZrO2), and zinc oxide (ZnO). The scatterer SCT may be selectively included in the first color conversion layer CCL1 or the second color conversion layer CCL2 in addition to the third sub-pixel SPXL3. The scatterer SCT may also be included in the second bank BNK2.

The first capping layer CPL1 may be disposed on the light conversion layer LCPL. The first capping layer CPL1 may be provided across the first to third sub-pixels SPXL1, SPXL2, and SPXL3. The first capping layer CPL1 may cover the color conversion layer CCL. The first capping layer CPL1 may prevent an impurity such as moisture or air from permeating from the outside and damaging or contaminating the color conversion layer CCL.

The first capping layer CPL1 may be an inorganic layer and may be formed by including silicon nitride (SiNx), aluminum nitride (AlNx), titanium nitride (TiNx), silicon oxide (SiOx), aluminum oxide (AlOx), titanium oxide (TiOx), silicon oxycarbide (SiOxCy), silicon oxynitride (SiOxNy), or the like.

The optical layer OPL may be disposed on the first capping layer CPL1. The optical layer OPL may serve to improve light extraction efficiency by recycling light provided from the color conversion layer CCL by total reflection. To this end, the optical layer OPL may have a refractive index relatively lower than that of the color conversion layer CCL. For example, the refractive index of the color conversion layer CCL may be about 1.6 to about 2.0, and the refractive index of the optical layer OPL may be about 1.1 to about 1.3.

The second capping layer CPL2 may be disposed on the optical layer OPL. The second capping layer CPL2 may be provided across the first to third sub-pixels SPXL1, SPXL2, and SPXL3. The second capping layer CPL2 may cover the optical layer OPL. The second capping layer CPL2 may prevent an impurity such as moisture or air from permeating from the outside and damaging or contaminating the optical layer OPL.

The second capping layer CPL2 may be an inorganic layer and may be formed by including silicon nitride (SiNx), aluminum nitride (AlNx), titanium nitride (TiNx), silicon oxide (SiOx), aluminum oxide (AlOx), titanium oxide (TiOx), silicon oxycarbide (SiOxCy), silicon oxynitride (SiOxNy), or the like.

The planarization layer PLL may be disposed on the second capping layer CPL2. The planarization layer PLL may be provided across the first to third sub-pixels SPXL1, SPXL2, and SPXL3.

The planarization layer PLL may include an organic material such as acrylic resin, epoxy resin, phenolic resin, polyamide resin, polyimide resin, polyester resin, polyphenylenesulfide resin, or benzocyclobutene (BCB). However, embodiments of the disclosure are not limited thereto, and the planarization layer PLL may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The color filter layer CFL may be disposed on the planarization layer PLL. The color filter layer CFL may include color filters CF (CF1, CF2, and CF3) that match a color of each pixel PXL. As the color filters CF (CF1, CF2, and CF3) that match the color of each of the first to third sub-pixels SPXL1, SPXL2, and SPXL3 are disposed, an image of a full color may be displayed.

The first color filter CF1 may be disposed in the first sub-pixel SPXL1 and may selectively transmit light emitted from the first sub-pixel SPXL1. The second color filter CF2 may be disposed in the second sub-pixel SPXL2 and may selectively transmit light emitted from the second sub-pixel SPXL2. The third color filter CF3 may be disposed in the third sub-pixel SPXL3 and may selectively transmit light emitted from the third sub-pixel SPXL3.

In an embodiment, the first color filter CF1, the second color filter CF2, and the third color filter CF3 may be a red color filter, a green color filter, and a blue color filter, respectively, but an embodiment of the disclosure is not limited thereto. For example, the first color filter CF1, the second color filter CF2, and the third color filter CF3 may be a green color filter, a red color filter, and a blue color filter, respectively.

The first color filter CF1 may overlap the first color conversion layer CCL1 in the thickness direction (for example, the third direction DR3) of the substrate SUB. The first color filter CF1 may include a color filter material that selectively transmits the light of the first color (or red). For example, in case that the first sub-pixel SPXL1 is a red pixel, the first color filter CF1 may include a red color filter material.

The second color filter CF2 may overlap the second color conversion layer CCL2 in the thickness direction (for example, the third direction DR3) of the substrate SUB. The second color filter CF2 may include a color filter material that selectively transmits the light of the second color (or green). For example, in case that the second sub-pixel SPXL2 is a green pixel, the second color filter CF2 may include a green color filter material.

The third color filter CF3 may overlap the scattering layer LSL in the thickness direction (for example, the third direction DR3) of the substrate SUB. The third color filter CF3 may include a color filter material that selectively transmits the light of the third color (or blue). For example, in case that the third sub-pixel SPXL3 is a blue pixel, the third color filter CF3 may include a blue color filter material.

According to an embodiment, a light blocking layer BM may be further disposed between the first to third color filters CF1, CF2, and CF3. As described above, in case that the light blocking layer BM is formed between the first to third color filters CF1, CF2, and CF3, a color mixing defect visible from a front surface or a side surface of the display device DD may be prevented. A material of the light blocking layer BM is not particularly limited and may be configured of various light blocking materials. As an example, the light blocking layer BM may include a black matrix, or may be implemented by stacking the first to third color filters CF1, CF2, and CF3 on each other.

The overcoat layer OC may be further disposed on the color filter layer CFL. The overcoat layer OC may be provided across the first to third sub-pixels SPXL1, SPXL2, and SPXL3. The overcoat layer OC may cover a lower member including the color filter layer CFL. The overcoat layer OC may prevent moisture or air from permeating into the above-described lower member. The overcoat layer OC may protect the above-described lower member from a foreign substance such as dust.

The overcoat layer OC may include an organic material such as acrylic resin, epoxy resin, phenolic resin, polyamide resin, polyimide resin, polyester resin, polyphenylenesulfide resin, or benzocyclobutene (BCB). However, an embodiment of the disclosure is not limited thereto, and the overcoat layer OC may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The outer film layer OFL may be disposed on the overcoat layer OC. The outer film layer OFL may be disposed on an outer side of the display panel DP to reduce an external influence. The outer film layer OFL may be provided across the first to third sub-pixels SPXL1, SPXL2, and SPXL3. According to an embodiment, the outer film layer OFL may include one or more of a polyethyleneterephthalate (PET) film, a low-reflective film, a polarizing film, and a transmittance controllable film, but an embodiment of the disclosure is not limited thereto.

According to an embodiment, the pixel PXL may include an upper substrate rather than the outer film layer OFL.

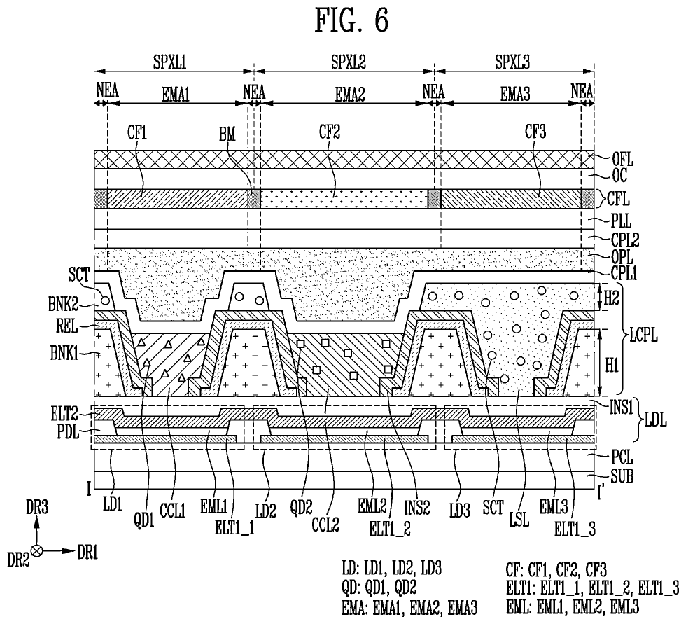

FIG. 6 is a schematic cross-sectional view taken along the line I-I′ according to another embodiment of the display panel of FIG. 2.

A content that may overlap the content described with reference to FIG. 5 may be omitted or simplified. Compared to the sub-pixel SPXL according to a first embodiment, the sub-pixel SPXL according to a second embodiment may further include a second insulating layer.

The second insulating layer may be disposed on a reflective electrode REL. For example, the second insulating layer may protect the reflective layer REL from external shock by covering the reflective layer REL.

The second insulating layer may include at least one of silicon oxide (SiOx), silicon nitride (SiNx), silicon oxynitride (SiOxNy), aluminum oxide (AlOx), and titanium oxide (TiOx).

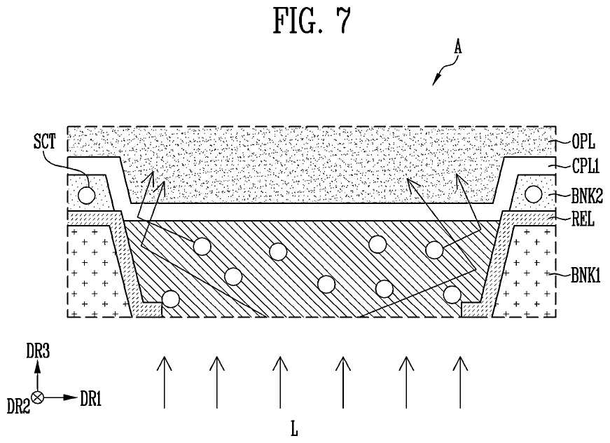

FIG. 7 is a schematic enlarged view illustrating portion A of FIG. 5.

Light L may be incident from the light emitting element layer LDL in the third direction DR3. The incident light L may be reflected by the reflective layer REL. Accordingly, the light L incident from the light emitting element layer LDL may be recycled, and emission efficiency of the light emitting element layer LDL may be improved.

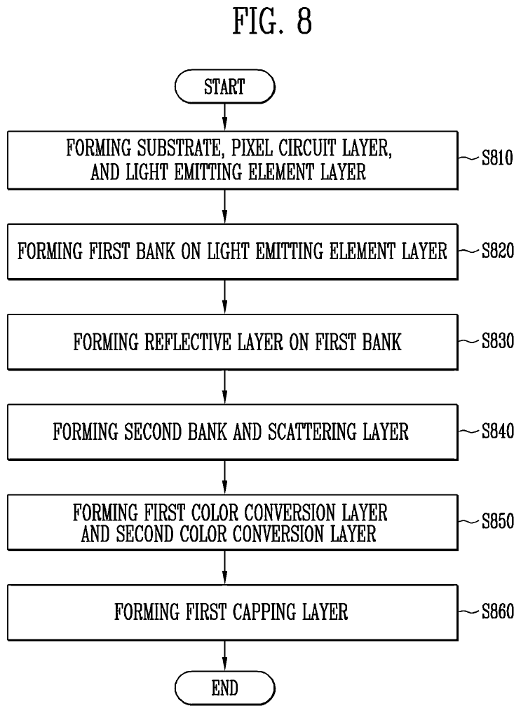

FIG. 8 is a schematic flowchart illustrating a method of manufacturing a display device according to an embodiment of the disclosure.

Referring to FIG. 8, the method of manufacturing the display device may include forming a substrate, a pixel circuit layer, and a light emitting element layer (S810), forming a first bank on the light emitting element layer (S820), forming a reflective layer on the first bank (S830), forming a second bank and a scattering layer on the reflective layer (S840), forming a first color conversion layer and a second color conversion layer (S850), and/or forming a first capping layer (S860). As described above with reference to FIG. 5, the optical layer OPL, the second capping layer CPL2, the planarization layer PLL, the color filter layer CFL, the overcoat layer OC, and the outer film layer OFL may be formed sequentially on the first capping layer CPL1, but a detailed description may be omitted below.

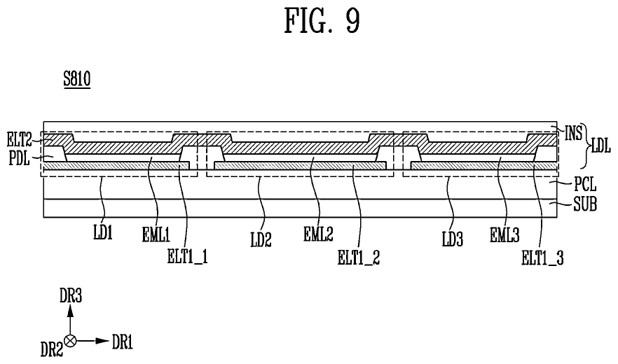

Hereinafter, the method of manufacturing the display device is described in detail with reference to FIGS. 9 to 18.

FIGS. 9 to 18 are schematic diagrams illustrating an example of the method of manufacturing the display device.

Referring to FIG. 9, the substrate SUB may be formed, the pixel circuit layer PCL may be formed on the substrate SUB, and the light emitting element layer LDL may be formed on the pixel circuit layer PCL.

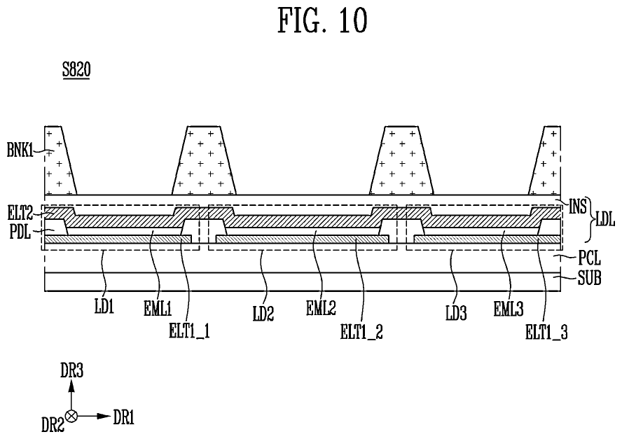

Referring to FIG. 10, the first bank BNK1 may be formed on the light emitting element layer LDL through an etching process. The first bank BNK1 may protrude in the thickness direction (for example, the third direction DR3) of the substrate SUB. The first bank BNK1 may be formed to have an inclined surface inclined at an angle (e.g., a predetermined or selectable angle) with respect to the substrate SUB.

The first bank BNK1 may include an organic material such as acrylic resin, epoxy resin, phenolic resin, polyamide resin, polyimide resin, polyester resin, polyphenylenesulfide resin, or benzocyclobutene (BCB). However, an embodiment of the disclosure is not limited thereto, and the first bank BNK1 may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

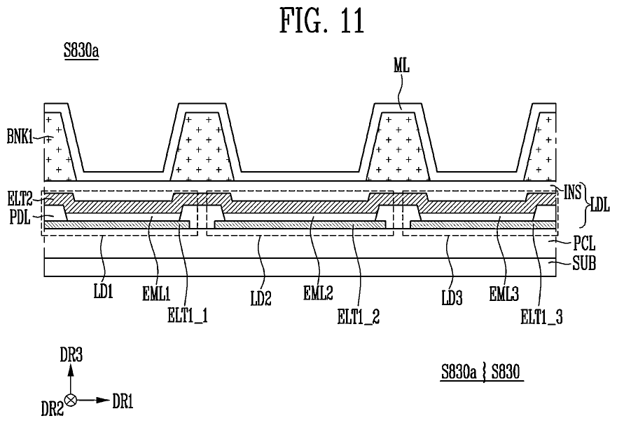

Referring to FIGS. 11 to 15, the reflective layer REL may be formed on the first bank BNK1. The reflective layer REL may at least partially cover a side surface and/or an upper surface of the first bank BNK1. For example, the reflective layer REL may include an inclined surface or a curved surface having a shape corresponding to a shape of the first bank BNK1.

The reflective layer REL may be formed through an etching process using a positive type photosensitive emulsion (photoresist). A specific formation process is as follows.

First, referring to FIG. 11, a metal layer ML may be formed on the first bank BNK1 in the first step S830a of step S830. The metal layer ML may include at least one of silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. However, the disclosure is not limited to the above-described example, and the metal layer ML may include one of various materials having a reflective property.

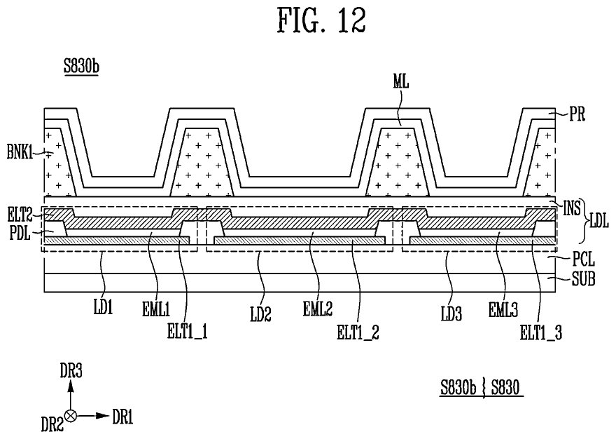

Referring to FIG. 12, a photoresist layer PR may be formed on the metal layer ML using the positive type photoresist in the second step S830b of step S830. The photoresist layer PR may be formed by coating a liquid positive type photoresist.

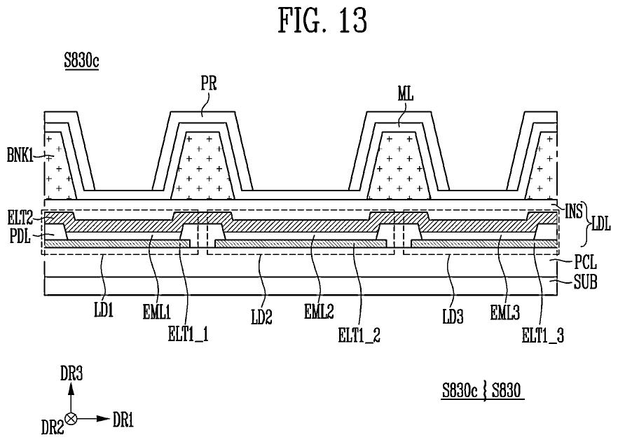

Referring to FIG. 13, the photoresist layer PR of an exposed portion may be removed through a development process in the third step S830c of step S830.

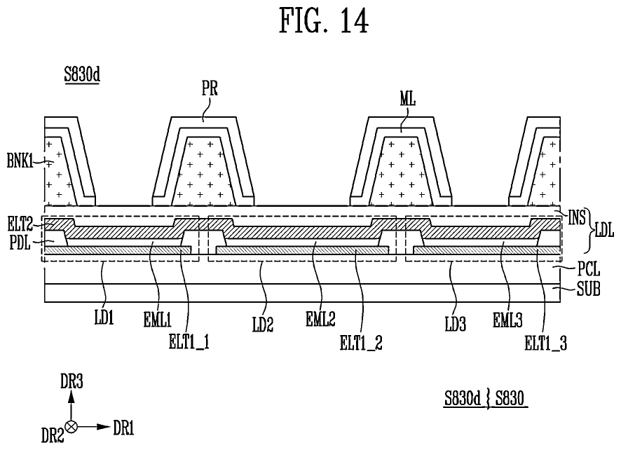

In addition, referring to FIG. 14, the metal layer ML of an exposed portion may be removed through an etching process using a remaining photoresist layer PR as a mask in the fourth step S830d of step S830.

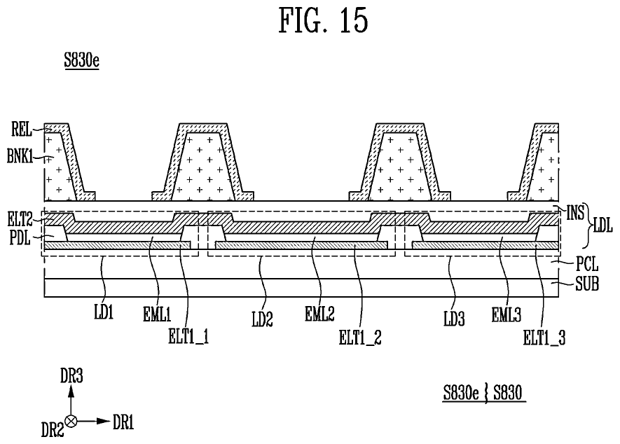

Referring to FIG. 15, the reflective layer REL may be formed by removing the remaining photoresist layer PR in the fifth step S830e of step S830.

In embodiments of the disclosure, by using the positive type photoresist when forming the reflective layer REL, a phenomenon that the photoresist layer PR is wet with developer and swells in a process of proceeding with a development process may not occur. Therefore, fine patterning of the reflective layer REL may be possible.

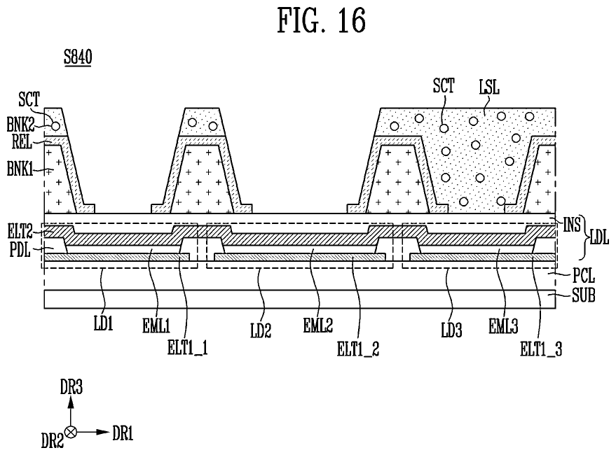

Referring to FIG. 16, the second bank BNK2 and the scattering layer LSL may be formed on the reflective layer REL. The second bank BNK2 and the scattering layer LSL may be patterned in a same process. The second bank BNK2 and the scattering layer LSL may be formed at a same time point. The second bank BNK2 and the scattering layer LSL may include a same material.

The second bank BNK2 and the scattering layer LSL may be formed to protrude in the thickness direction (for example, the third direction DR3) of the substrate SUB. The second bank BNK2 may include an organic material such as acrylic resin, epoxy resin, phenolic resin, polyamide resin, polyimide resin, polyester resin, polyphenylenesulfide resin, or benzocyclobutene (BCB). However, an embodiment of the disclosure is not limited thereto, and the second bank BNK2 may include various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The second bank BNK2 and the scattering layer LSL may include a suitable liquid-repellent material. The liquid-repellent material may include an organic polymer material having liquid repellency. For example, the liquid-repellent material may include a polymer material in which a fluorine group (F) is mixed with an organic material such as polyimide (for example, a vinyl-based polymer having a perfluoroalkyl group (Rf group) in a side chain or silicone containing a perfluoroalkyl group).

The second bank BNK2 and the scattering layer LSL may include the scatterer SCT. As an example, the scatterer SCT may include at least one of barium sulfate (BaSO4), calcium carbonate (CaCO3), titanium oxide (TiO2), silicon oxide (SiO2), aluminum oxide (Al2O3), zirconium oxide (ZrO2), and zinc oxide (ZnO).

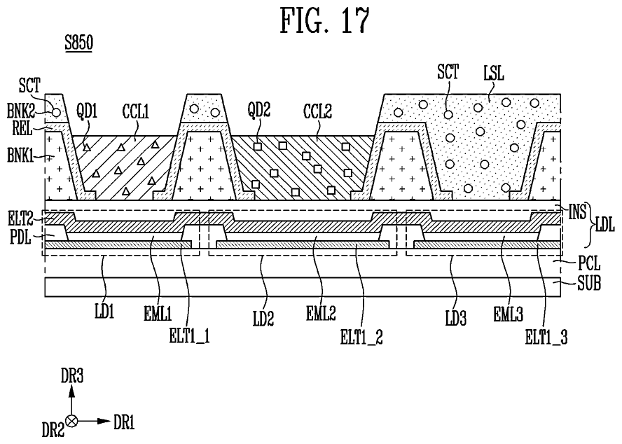

Referring to FIG. 17, the first color conversion layer CCL1 and the second color conversion layer CCL2 may be formed. For example, the first color conversion layer CCL1 disposed in the first sub-pixel SPXL1 (see FIG. 5) and the second color conversion layer CCL2 disposed in the second sub-pixel SPXL2 (see FIG. 5) may be formed. The first color conversion layer CCL1 and the second color conversion layer CCL2 may be formed to protrude in the thickness direction (for example, the third direction DR3) of the substrate SUB.

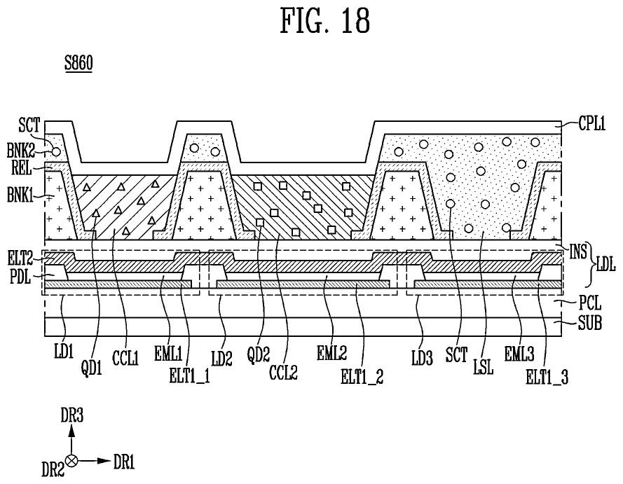

Referring to FIG. 18, the first capping layer CPL1 may be formed on the second bank BNK2, the first color conversion layer CCL1, the second color conversion layer CCL2, and the scattering layer LSL. The first capping layer CPL1 may be an inorganic layer and may be formed by including silicon nitride (SiNx), aluminum nitride (AlNx), titanium nitride (TiNx), silicon oxide (SiOx), aluminum oxide (AlOx), titanium oxide (TiOx), silicon oxycarbide (SiOxCy), silicon oxynitride (SiOxNy), or the like.

Although not shown in FIG. 18, after the first capping layer CPL1 is formed, the optical layer OPL, the second capping layer CPL2, the planarization layer PLL, the color filter layer CFL, the overcoat layer OC, and the outer film layer OFL may be sequentially formed.

According to an embodiment of the disclosure, as the second bank BNK2 and the scattering layer LSL of the third sub-pixel SPXL3 are formed at a same time point, the number of masks may be reduced, and a manufacturing process may be simplified, thereby reducing a process cost. In addition, by using a positive type photoresist during a manufacturing process of the reflective layer REL, fine patterning of the reflective layer REL may be possible.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A method of manufacturing a display device, the method comprising:
forming a substrate, a pixel circuit layer, and a light emitting element layer;
forming a first bank on the light emitting element layer;
forming a reflective layer on the first bank;
forming a second bank and a scattering layer on the reflective layer;
forming a first color conversion layer and a second color conversion layer in an area surrounded by the second bank on the substrate; and
forming a first capping layer on the scattering layer, the first color conversion layer, and the second color conversion layer,
wherein the reflective layer is formed through an etching process using a positive type photosensitive emulsion.

2. The method according to claim 1, further comprising:
forming an insulating layer disposed on the reflective layer and surrounding the reflective layer.

3. The method according to claim 1, wherein the reflective layer surrounds a side surface and an upper surface of the first bank.

4. The method according to claim 1, wherein
each of the first color conversion layer and the second color conversion layer includes a color conversion particle capable of converting a color, and
a surface of the second bank faces the first bank and the reflective layer.

5. The method according to claim 1, wherein
the second bank and the scattering layer include a scatterer, and
the scatterer includes at least one of barium sulfate, calcium carbonate, and titanium oxide.

6. The method according to claim 1, wherein the second bank and the scattering layer include a liquid-repellent material.

7. The method according to claim 1, wherein each of the first bank and the second bank has one of a square shape, a rectangular shape, and a trapezoidal shape.

8. The method according to claim 1, further comprising:
forming a first capping layer on the first and second color conversion layers.

9. The method according to claim 1, wherein the second bank and the scattering layer are formed at a same time point.

10. The method according to claim 1, wherein the forming of the reflective layer on the first bank comprises:
forming a metal layer on the first bank;
forming a photoresist layer on the metal layer using the positive type photosensitive emulsion;
removing the photoresist layer of a portion exposed through a development process; and
forming the reflective layer by etching the metal layer using the remaining photoresist layer.

11. A display device comprising:
a substrate including an area where first to third sub-pixels are formed;
a first bank formed on the substrate and protruding in a first direction;
a reflective layer formed on the first bank;
a second bank disposed on the reflective layer and overlapping the first bank;
a first color conversion layer formed in the first sub-pixel and formed in an area surrounded by the first bank on the substrate;
a second color conversion layer formed in the second sub-pixel and formed in an area surrounded by the first bank on the substrate; and
a scattering layer formed in the third sub-pixel,
wherein the scattering layer and the second bank include a same material.

12. The display device according to claim 11, further comprising:
an insulating layer disposed on the reflective layer and surrounding the reflective layer.

13. The display device according to claim 11, wherein the reflective layer surrounds a side surface and an upper surface of the first bank.

14. The display device according to claim 11, wherein
each of the first color conversion layer and the second color conversion layer includes a color conversion particle capable of converting a color, and
a surface of the second bank faces the first bank and the reflective layer.

15. The display device according to claim 11, wherein
the second bank and the scattering layer include a scatterer, and
the scatterer includes at least one of barium sulfate, calcium carbonate, and titanium oxide.

16. The display device according to claim 11, wherein the second bank and the scattering layer include a liquid-repellent material.

17. The display device according to claim 11, wherein each of the first bank and the second bank has one of a square shape, a rectangular shape, and a trapezoidal shape.

18. The display device according to claim 11, further comprising:
a first capping layer on the first and second color conversion layers.

19. The display device according to claim 11, further comprising:
an insulating layer disposed on the reflective layer and surrounding the reflective layer, wherein
the reflective layer surrounds a side surface and an upper surface of the first bank,
each of the first color conversion layer and the second color conversion layer includes a color conversion particle capable of converting a color, and
a surface of the second bank faces the first bank and the reflective layer.

20. The display device according to claim 11, further comprising:
a first capping layer on the first and second color conversion layers, wherein
the second bank and the scattering layer include a scatterer,
the scatterer includes at least one of barium sulfate, calcium carbonate, and titanium oxide, and
each of the first bank and the second bank has one of a square shape, a rectangular shape, and a trapezoidal shape.
